(19) United States
(12) Patent Application Publication
(10) Pub. No.: US 2020/0095666 A1
(43) Pub. Date: Mar. 26, 2020

(54) ABRADABLE COATING

(71) Applicant: OERLIKON METCO AG, WOHLEN, Wohlen (CH)

(72) Inventors: Richard K. SCHMID, Frauenfeld (CH); Malko GINDRAT, Wohlen (CH); Gregory SZYNDELMAN, Villigen (CH)

(73) Assignee: OERLIKON METCO AG, WOHLEN, Wohlen (CH)

(21) Appl. No.: 16/484,001

(22) PCT Filed: Feb. 7, 2018
(86) PCT No.: PCT/EP2018/053089

§ 371 Date: Aug. 6, 2019

Related U.S. Application Data
(60) Provisional application No. 62/455,967, filed on Feb. 7, 2017.

(51) Int. Cl. C23C 4/134; C23C 28/00; C23C 4/11; C23C 14/00

(52) U.S. Cl. CPC C23C 4/134; C23C 28/36; C23C 14/0057; C23C 4/11; C23C 28/3455

(57) ABSTRACT

A method of forming an abradable coating includes forming a plasma; introducing a coating material, as a powder having particles in the range between 1 and 50 μm, carried by a delivery gas into the plasma, having a sufficiently high specific enthalpy for at least partially melting some of the powder and vaporizing at least 5% by weight of the powder, to form a vapor phase cloud of vapor and particles; forming a plasma beam by maintaining a process pressure between 50 and 2000 Pa; defocussing the plasma beam by maintaining a process pressure between 50 and 2000 Pa; and forming from the vapor phase cloud an abradable coating, comprising columnar structures. Advantageously, the columnar structured abradable coating has an erosion resistance smaller than 30 s/mils, preferably in the range of 5 to 27 s/mils, more preferably in the range 10-25 s/mils, still more preferably in the range 15-20 s/mils.

The invention relates to clearance control, such as through abradable coatings, in gas turbine engines and a method of producing abradable coatings. In particular, the invention relates to abradable coatings applied on a turbine component such as a casing or shroud by a vacuum plasma spray process, such as plasma spray physical vapor deposition.

### BACKGROUND

The application of abradable coatings is used in many applications, in particular as abradable seals in aircraft or stationary gas turbines. Typically, the sealings are produced on segments or shrouds between the rotating components, such as blades or vanes, and stationary parts, such as casings or shrouds in the gas turbine. The sealings ensure that the hot gases cannot leak or escape at the clearance between for instance the vane tip and the shroud. Preventing leakage helps directing all the gas towards the rotating components, thus increasing engine efficiency and power output. The selection of material and microstructure of the abradable layer is critical but the choice becomes limited when considering the high temperatures conditions in the combustion chamber.

Typically, the rotating compressor or rotor of an axial flow gas turbine comprises a plurality of blades attached to a shaft which is mounted in a shroud. In operation, the shaft and blades rotate inside the shroud. The gap between the inner surface of the turbine shroud and the moving blade tip is defining the clearance. This gap should, in a perfect situation, be close to 0 mm. In real condition, such as in a jet engine or stationary gas turbine, this is mechanically impossible because of intrinsic casing distortion. Also, the expansion of the rotor due to the high rotating velocities and due to the high gas temperatures inside the engine or turbine prevents achieving this ideal limit. Moreover, for aircraft gas turbines, other factors during operation, such as landing, take off, or instabilities during the flight, can cause a minimal misalignment of the axis of the engine which will slightly moves the blade tip closer to the shroud for a very short time period.

Thick abradable coatings are typically produced on the inner walls of the casing or shroud to allow a good sealing between the blade tip and the shroud. The rubbing of the blade tip on the thick abradable coating will not have a constant penetration in the coating during operation, nor during starting/stopping the engine, due to the factors described above. Therefore, it is necessary to control the wearing of the abradable coating during the different operational phases of the turbine.

In order for the turbine blade tip to cut controlled grooves in the abradable coating, the material from which the coating is made must abrade relatively easily without wearing down the blade tips. This requires a careful balance of material choice of the blade tip and materials in the coatings. Moreover, it requires producing a coating with specific microstructures which on the one hand is soft enough to abrade without detaching from the substrate. And on the other hand, not too hard to prevent damaging the blade tip. The choice of material becomes even more limited when high temperature performance requirements are considered.

Abradable coatings are in most of the cases the last coating applied on a metallic substrate and are part of a complete thermal barrier coating (TBC) system. These thermal barrier coatings, described more in detail in for instance U.S. Pat. No. 5,238,752, are necessary because of the exposure of turbine components to high gas temperatures in the engine. The TBC is capable to providing a temperature reduction seen by the components of between 140° and 170°. Combined with active cooling of the turbine components, a TBC can enable operation of the engine at combustion gas temperatures in excess of 250° C. above the melting temperature of superalloys. Another advantage of thermally protecting the components is the extension of the component life and the reduction in the frequency of servicing.

TBC systems comprise typically several layers applied on a turbine component in the following order:
1. an optional metallic barrier layer with a composition close to the substrate, for example a NiAl or NiCr based alloy;
2. a metallic bond coat which serves as hot gas corrosion protection and also as interface layer between the metallic substrate and the ceramic top layer. The bond coat could be manufactured using NiAl, NiPtAl, PtAl, or a MCrAlY alloy, where M stands for one of the metals, such as Fe, Ni, or Co, or a combination of Ni and Co;
3. an optional oxide ceramic protective layer or thermal growth oxide (typically formed with substrate temperatures around 1000° C. under the influence of an added oxygen flow during the deposition process), for example predominantly of Al₂O₃ or other oxides;
4. an oxide ceramic thermal barrier coating (TBC), for example of stabilized zirconium oxide or rare earth zirconate;
5. an optional smoothing oxide layer or cover layer; and
6. an additional abradable coating, for specific components where a sealing is necessary.

The thermal barrier coating usually has a thickness in the range from 0.2 mm to a few mm, and can be deposited either by thermal spraying or electron beam physical vapor deposition. These processes allow producing specific microstructures, such as porous coatings or columnar structures for increased high strain tolerance, which increase the insulation effect by reducing the thermal conductivity in comparison to the bulk ceramic material. Creating the coating microstructure is done in parallel with a selection of specific materials having low thermal conductivity. The material of choice for TBCs has been zirconia-based ceramics, such as Yttria (Y₂O₃) stabilized zirconia (ZrO₂), YSZ, where the wt % of Yttria would be typically between 6-8%, but also any rare earth based zirconate, such as dysprosia-stabilized zirconia.

Abradable coatings can be produced using similar materials, coating properties and coating processes as for TBCs. In some cases, as described in U.S. Pat. No 4,936,745, the TBC layer has the dual function of a thermal insulation coating and an abradable coating.

Thermal spraying, in particular atmospheric plasma spraying (APS), is the process of choice to produce thick and porous coatings. The achieved porosities of up to 20%, however, are usually good for a thermal barrier coating but often not high enough to ensure a good controlled wear if the coating is used as an abradable coating. Thus, these coatings can have a negative effect on the blade tip when it is rubbing against the coating. The tips either overheat or wear off too rapidly because of the abrasive nature of the ceramic material. Consequently, special requirements have to be made for the material of the blade tip, respectively of the coating on the blade tip (“blade tipping”), such as cubic boron nitride and silicon carbide. While these abrasive tipping improve the cutting behavior of the blade on the dual function TBC/abradable coating, they are quite expensive to apply.

As an alternative, according to a well-known atmospheric plasma spraying method of applying ceramic abradable coatings (see for instance U.S. Pat. No. 5,530,050.), a blend of ceramic powder and polymer (typically 6% polyester) is deposited by thermally spray on a turbine component. Subsequently, the polyester is burnt away during a post heat treatment process. This results in a coating having a much higher porosity (up to 35%) than coatings sprayed without the polymer. These high porosity coatings ensure a lower thermal conductivity, improve the sintering resistance and improve the abradability when cut by untipped, cubic boron nitride (cBN), or silicon carbide (SiC) tipped blade.

As described above, engine manufacturers are challenged to develop and produce engines having increased fuel efficiency and reduced gas emissions. To achieve this goal, engines are designed with increased combustion temperatures and with reduced weight of its components. Consequently, components made of the best metallic superalloy materials would have to withstand temperatures above 1200° C. To face these challenges, promising materials have been developed to produce light weight structural components, such as carbon fiber reinforced silicon carbide composites (C/SiC) and silicon carbide fiber reinforced silicon carbide composites (SiC/SiC). These materials are most commonly designated as ceramic matrix composites (CMC). While components made of such materials are mechanically very stable at high temperature, they are vulnerable to the exposure of water vapor. Such exposure reduces their economic life and performance considerably. Consequently, these components have to be protected by environment barrier coatings (EBC) to prevent the water vapor induced degradation during operation. The properties of EBC systems are on the one hand very close to the TBC systems described before with respect to be high temperature and thermal shock resistance. On the other hand, they also provide a protection of the CMC material with respect to the water vapor present in the combustion gas.

Unlike TBCs, EBCs need to be dense and tight to any penetration of the water vapor into the substrate, as well as need to match the expansion coefficient of the substrate to ensure a crack and pore free coating. Typical EBC systems are made of a bond coat and a top coat. The materials for the bond coat is typically a Si-based metal. For the top coat typically mullites (Al₂O₃ SiO₂) with different proportion of Al₂O₃ and SiO₂, or silicates materials such as Yb₂O₃, Yb₂Si₂O₇, Yb₂SiO₅ and/or a combination of both mullites and silicates are used.

With the use of new materials for the components, in particular for blades and shrouds, and with the production of new coating systems, such as EBC systems having different chemistries than the known TBC systems, new type of abradable coatings will be needed. These new abradable coatings need to have an even higher temperature and thermal shock resistance, ensure a compatible chemistry with both TBCs and EBCs, and produce an excellent seal between the abradable coating and the (for instance CMC) blade component.

### SUMMARY OF THE INVENTION

Thus, it is an objective of the invention to provide a method for producing an abradable coating on a turbine component, such as a segment or shroud, so that the material deposited on the turbine component allows to be abraded in a controlled way during operation of the turbine and which at the same time provides high temperature strain and shock resistance, and which is, moreover, compatible with production methods of “lower” layers of TBC systems and EBC systems. It is another objective of the invention to provide a method of applying an abradable coating which is more economic compared to APS produced abradable coating by removing the need to use complex blends and post-treatment of the coating in order to produce higher porosities.

This objective is achieved by the plasma spray physical vapor deposition (PS-PVD) method described her below.

In plasma spray physical vapor deposition, a coating deposited on a substrate surface by spraying onto the surface of a metallic or ceramic matrix composite in the form of a powder or vapor jet. Such a jet is transported and directed by a plasma jet exiting a plasma torch operated at pressures below 10,000 Pa. In the present invention, the abradable coating material is injected in the plasma in form of a powder, preferably an agglomerated powder, which allows breaking up into smaller powder fraction inside the plasma torch, to completely or partially evaporate through the high specific enthalpy of the plasma jet allowing the formation of an anisotropic structured coating or columnar structure onto the surface that can be used as an abradable coating.

Advantageously, the resulting columnar structured abradable coating allows the production of a well-defined cutting path into the coating by blade tip when the latter penetrates and rubs the abradable coating under operational conditions of the turbine engine. The cutting paths through the abradable coating according to the invention is better defined and limited in comparison to cutting paths that blade tips create through abradable coatings produced with classical atmospheric plasma spraying (APS). Advantageously, the columnar structured abradable coatings produced by PS-PVD have an anisotropic structure and a porosity which is considerably larger than the porosity achieved (with a maximum of 35%) by APS produced coatings. This is also reflected in the thermal conductivity of the coatings: whereas the thermal conductivity for instance bulk 7YSZ (zirconate stabilized with 7 wt % Yttria) is 3.0 W/m·K@25° C., for an APS produced 7YSZ TBC it is 1-1.4 W/m·K, and an EB-PVD produced columnar 7YSZ coating it is 1.2-2.2 W/m·K, columnar structured abradable coatings according to the invention show thermal conductivities smaller than 1 W/m·K, even as low as 0.8 W/m·K.

While the columns in the PS-PVD produced abradable coatings according to the invention will wear due the blade tip passing over the columns, advantageously this occurs only there where the blade is rubbing the columns. In other words, the passing blade tip does not pull away (parts of) neighbouring columns. This contrasts with for instance EB-PVD produced columns where the blade tip chips away part of neighbouring columns, so that the side wall of the cutting path becomes more ragged. Thus, advantageously, the defined path and sharp cutting path walls (essentially the sides of the abradable columnar structures) allows for a better sealing of the clearance gap in the turbine, thereby improving the latter's efficiency.

The inventors note that other methods, such as electron beam physical vapor deposition (EB-PVD), allow producing crystalline columnar structures for TBCs. Such methods, however, do not produce good abradable columnar structures, as the crystalline columns produced using such methods would be too close or dense to each other. For instance, the typical column width of EB-PVD produced structures is ≤10 μm with typically ˜10 columns/100 μm in a direction parallel to or along the substrate (so the intercolumn space is in the range of 0 to 2 μm). In comparison, the width and linear density of PS-PVD produced columns can be tuned from 5-15 μm with 7 columns/100 μm (intercolumn space >5 μm) to 10-50 μm with 4 columns/100 μm (intercolumn space 0 to 5 μm). This is reflected in the high erosion resistance of EB-PVD produced coatings compared to PS-PVD produced coatings. Erosion resistance is measured by directing a jet of sand particles at a predefined angle and measuring the time necessary to lose 25.4 μm (one mil) of coating thickness. PS-PVD produced columnar structured abradable coatings have erosion resistances between 5 and 28 s/mils, preferably between 10 and 25 s/mils, more preferably between 15 and 20 s/mils. In comparison EB-PVD produced columnar structured coatings have an erosion resistance in excess of 30 s/mils, even up to 45 à 50 s/mils. Thus advantageously, the PS-PVD produced columnar structured abradable coating according to the invention have an erosion resistance which is a factor 2 to 10 smaller than ES-PVD produced columnar structured coatings. The lower erosion resistance allows waring down part of the columnar structures in small portions, again supporting the creation of a well-defined cutting path.

Another advantage of the PS-PVD method for producing columnar structured abradable coatings is that it is a very versatile process. Upon changing the process parameters different types of coating microstructures can be produced, such as columnar structured coatings, porous coatings, and dense coatings, all using the same piece of equipment. Advantageously, PS-PVD produced dense coatings may be made gas tight. Moreover, changing process parameters during the spraying process allows production of gradient abradable coatings. In an embodiment a gradient abradable coating is formed by a three-layered structure comprising a lower dense lamellar layer, an intermediate porous layer, and a top columnar structured abradable layer. Such gradient abradable coatings are especially advantageous in combination with EBC coatings, where dense lamellar layer is necessary to protect the turbine component.

In another embodiment, the PS-PVD method is applied starting with operating parameters for producing a dense layer having a chemistry close to the EBC and finish with operating parameters for producing a columnar structured layer with a different chemistry as abradable layer. Thus, such a gradient abradable coating ensures a perfect bond between the EBC and the abradable coating. Chemistries, that is the composition of the materials, may be changed during the PS-PVD process by using several powder injectors and changing the powder feed rates during the process. Advantageously, the PS-PVD method can produce high performant EBC coatings due to the conservation of the crystallinity of the mullites or silicate materials.

In fact, in an advantageous embodiment, the PS-PVD method is used to produce the complete coating system, providing a CMC component as a substrate, depositing an EBC on top of the CMC component (with optionally an appropriate intermediate bond coat), providing a gradient abradable coating on top of the EBC, wherein the gradient coating comprises at least a dense layer with a chemistry commensurate with the EBC coating and a columnar structured abradable coating on the top for sealing the clearance gap.

Thus, in an embodiment a method of forming an abradable coating comprises (i) forming a plasma; (ii) introducing a coating material, in the form of a powder having particles in the range between 1 and 50 μm, carried by a delivery gas into the plasma, the plasma having a sufficiently high specific enthalpy for at least partially melting some of the powder and vaporizing at least 5% by weight of the powder, so as to form a vapor phase cloud of vapor and particles; (iii) forming a plasma beam by maintaining a process pressure between 50 and 2000 Pa; (iv) defocussing the plasma beam including the vapor phase cloud; and (v) forming from the vapor phase cloud onto a substrate surface an abradable coating, being part of an insulating layer system, the abradable coating comprising columnar structures.

In another embodiment, the method comprises forming an abradable coating comprising columnar structures wherein the columnar structured abradable coating has an erosion resistance smaller than 30 s/mils (mils=25.4 μm), preferably in the range of 5 to 27 s/mils, more preferably in the range 10-25 s/mils, still more preferably in the range 15-20 s/mils.

In yet another embodiment, the method comprises tuning the erosion resistance of the abradable coating through controlling at least one of the amount of hydrogen plasma gas, the surface temperature of substrate, and the powder feet rate.

In a further embodiment the surface temperature of the substrate during the coating process is tuned to a value in the range 500° C. to 1100° C., preferably in the range 950° C. to 1050° C. Whereas in another embodiment, the amount of hydrogen plasma gas is tuned in the range of 0 NLPM to 10 NLPM. And in yet another embodiment, the total powder feed rate is tuned in the range of 5 g/min to 60 g/min.

In another embodiment the columnar structures of the abradable coating have a feathery or cauliflower micro-structure. The columnar structures of abradable coating having such a feathery of cauliflower microstructure may be structured such that, in operation within a turbine or engine, a top part of the columnar structure may be chipped away by vane-tip, leaving a bottom part unaffected.

In an embodiment of the invention forming the abradable coating comprises using a plasma spray physical vapor deposition (PS-PVD) system.

In another embodiment, the method comprises depositing a gradient abradable layer. As an example, deposition of such a gradient abradable layer may comprise depositing a first sub-layer comprising a lamellar dense structure and a third sub-layer, subsequent to depositing the first sub-layer, comprising the columnar structures. Alternatively, the method may comprise depositing a second sub-layer intermediate between the first sub-layer and the third sub-layer, wherein the second sub-layer comprises a mixed phase crumbly structure. Alternatively still, the method may comprise forming the first sublayer with a chemical composition commensurate with a chemical composition of a lower layer of the insulating layer system and forming the third sub-layer with a different chemical composition for forming the columnar structured abradable coating.

According to another aspect the invention provides a turbine component or engine component, comprising an insulating layer system wherein an outer layer of the insulating layer system forms an abradable coating comprising columnar structures. Advantageously, the columnar structured abradable coating has an erosion resistance smaller than 30 s/mils (mils=25.4 μm), preferably in the range of 5 to 27 s/mils, more preferably in the range 10-25 s/mils, still more preferably in the range 15-20 s/mils.

These and other aspects of the invention will be apparent from and elucidated with reference to the embodiments described hereinafter. Appreciate, however, that these embodiments may not be construed as limiting the scope of protection for the invention. They may be employed individually as well as in combination. The invention is explained in more detail below with reference to the schematic drawings.

### BRIEF DESCRIPTION OF THE DRAWINGS

FIG. 1A schematically shows a turbine/engine component, in this case a blade.

FIG. 1B schematically shows a first embodiment of a coating system according to the invention.

FIG. 1C schematically shows a second embodiment of a coating system according to the invention.

FIG. 2 schematically shows a close-up of a blade tip cutting a path through an abradable columnar coating according to the invention.

FIG. 3 schematically shows a close-up of the micro-structure of a column of the abradable coating according to the invention

FIG. 4A schematically shows a first micro-structure obtainable with the PS-PVD process according to the invention

FIG. 4B schematically shows a second micro-structure obtainable with the PS-PVD process according to the invention

FIG. 4C schematically shows a third micro-structure obtainable with the PS-PVD process according to the invention

FIG. 5 schematically shows another embodiment of the abradable coating according to the invention, comprising a gradient coating.

### DESCRIPTION OF THE PREFERRED EMBODIMENTS

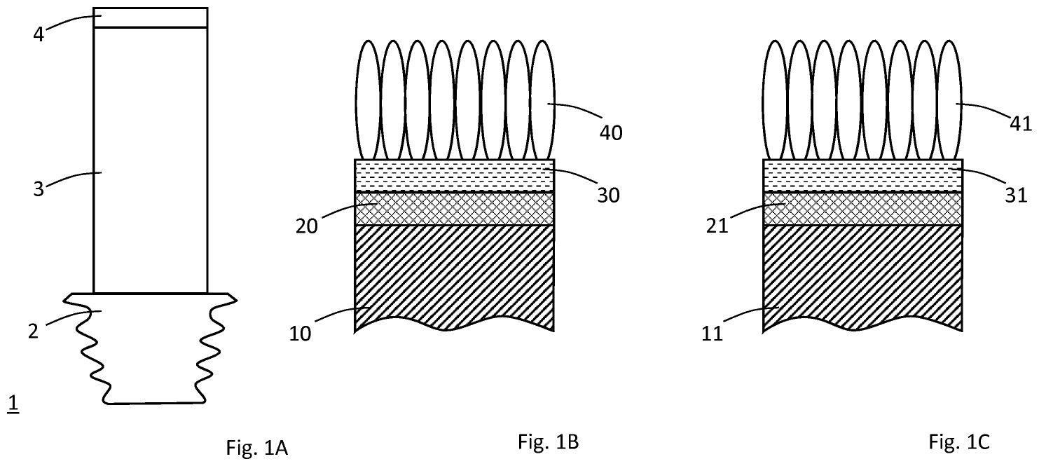

FIG. 1 schematically shows a gas turbine engine component, in this case a blade unit 1 comprising a base 2, a vane or air foil 3, and a vane-tip 4 which may be assembled in a gas turbine as either a stator blade unit or a rotor blade unit. The rotating compressor or rotor of an axial flow gas turbine consists of a plurality of such blade units attached to a shaft which is mounted in a shroud. In operation. The shaft and blades rotate inside the shroud. The inner surface of the turbine shroud 10,11 is most preferably coated with an abradable material which functions as a seal for the clearance gap between vane-tip 4 and shroud 10,11 in order to increase the efficiency of the turbine. FIGS. 1B and 1C schematically show two embodiments of the present invention in which a metallic substrate 10, respectively a ceramic matrix composite (CMC) substrate 11, of a turbine component such as the shroud is covered with an appropriate bond coat 20,21. Such a bond coat is optional. On top of the bond coat a thermal barrier coating (TBC) 30, respectively an environmental barrier coating (EBC) 31, is deposited. On top of these later barrier coatings, a columnar structured abradable coating 40,41 according to the invention has been deposited using the PS-PVD process. Advantageously, the columnar structured abradable coating 40,41 using the PS-PVD process is softer and more porous, respectively has a lower linear column density and more feathery structure of a column, relative to EB-PVD produced abradable coatings.

In order that the anisotropic micro-structure of the columnar structured abradable coating 40,41 is produced, a plasma must be produced with sufficiently high specific enthalpy so that a substantial portion—amounting to at least 5% by weight, of the coating material changes into the vapor phase. The portion of the vaporized material which may not fully change into the vapor phase can amount to up to 70%. The plasma is produced in a burner with an electrical DC current and by means of a pin cathode and a ring-like anode. The power supplied to the plasma, respectively the effective power, must be determined empirically with respect to the resulting coating structure. The effective power, according to experience typically between 50% and 55% of the electrical power supplied to the plasma gun, is in the range from 40 to 80 kW.

The process pressure of the PS-PVD method for producing the abradable coatings according to the invention has a value between 50 and 2000 Pa, preferably between 100 and 800 Pa. Powder is injected into the plasma from 1 or more (such as 2, 3, or 4) injectors using a delivery gas. The process gas for the production of the plasma is a mixture of inert gases, in particular a mixture of argon Ar and helium He, with the volume ratio of Ar to He advantageously lying in the range from 2:1 to 1:4. The total gas flow is in the range from 30 to 150 NLPM (Normal Litres Per Minute). The total powder feed rate lies between 5 and 60 g/min, preferably between 10 and 40 g/min. The plasma has a sufficiently high specific enthalpy for at least partially melting some of the powder and vaporizing at least 5% by weight of the powder, so as to form a vapor phase cloud of vapor and particles. A plasma beam is formed by maintaining a process pressure between 50 and 2000 Pa and defocused, including the vapor phase cloud of vapor and particles in the defocusing plasma. The substrate is preferably moved with rotating or pivoting movements relative to this cloud during the material application. Typically, the substrate 10,11 surface temperature during the coating process is in the range of 500° C. and 1100° C. and is heated using the plasma jet. Alternatively, however, the surface temperature may also be controlled using other heat sources, such as another plasma gun, induction, or quartz lamps. The spray distance from the plasma gun to the substrate typically is around 900 mm. Using the PS-PVD process, the abradable coating is built up by growth of the columnar structure. The total coating thickness has values between 20 μm and 2000 μm, preferably values between 200 μm and 1000 μm.

An oxide ceramic material, or a material which includes oxide ceramic components, is suitable for the manufacture of a columnar structured abradable coating 40,41 using the method in accordance with the invention, with the oxide ceramic material being in particular a zirconium oxide, in particular a zirconium oxide which is fully or partly stabilized with yttrium, cerium or other rare earths. The material used as the stabilizer is added to the zirconium oxide as an alloy in the form of an oxide of the rare earths, for example yttrium Y, cerium or scandium, with—for the example of Y—the oxide forming a portion of 5 to 20% by weight, such as 8%.

In order that the powder beam is reshaped by the defocusing plasma into a vapor phase cloud of vapor and particles from which a coating results with the desired micro-structure, the powdery starting material must have a very fine primary grain (preferably in the range 1-3 μm) which may (loosely) agglomerate to larger powder particles. The size distribution of the powder particles is typically determined by means of a laser scattering method. The size distribution of the powder particles lies to a substantial portion in the range between 1 μm and 50 μm, preferably between 3 μm and 25 μm. Various methods can be used to manufacture the powder particles: for example, spray drying or a combination of melting and subsequent breaking and/or grinding of the solidified melt.

In case of a metallic turbine component substrate 10, comprising for instance a Ni or Co base alloy, optional bond coating 20 may comprise an NiAl alloy or an NiCr alloy. TBC 30, for instance made using Zirconium oxide stabilized with yttrium Y (such as ZrO₂-8% Y₂O₃) as the coating material, typically has a coating thickness ranging between 10 μm and 300 μm, preferably between 25 μm and 150 μm. TBC 30 in particular comprises a metal aluminide, or an MCrAlY alloy, with M standing for one of the metals Fe, Co or Ni or of a ceramic oxide material. It preferably has an either dense, columnar, directional or unidirectional structure.

In case of a CMC turbine component substrate 11, comprising carbon fiber reinforced silicon carbide composites (C/SiC) and silicon carbide fiber reinforced silicon carbide composites (SiC/SiC), the optional bond coat 21 may comprise a Si-based metal. EBC 31, for instance made of mullites (Al₂O₃ SiO₂) with different proportion of Al₂O₃ and SiO₂, or silicates materials such as Yb₂O₃, Yb₂Si₂O₇, Yb₂SiO₅ and/or a combination of both mullites and silicates, typically has a coating thickness ranging between 10 μm and 300 μm, preferably between 25 μm and 150 μm.

The part layers of the complete coating system are preferably all applied in a single work cycle without interruption using the PS-PVD processes. After the application, the coating system may be heat treated as a whole, if necessary.

In the plasma spraying process of the invention an additional heat source, such as another plasma gun, a quartz lamp, or induction source, can also be used in order to carry out the deposition of the coating material within a predetermined temperature range. The temperature of the substrate 10, 11 is pre-set in the range between 500° C. and 1100° C., preferably in the temperature range 950° C. to 1050° C. An infrared lamp or plasma jet can, for example, be used as an auxiliary heat source. In this arrangement a supply of heat from the heat source and the temperature in the substrate which is to be coated can be controlled or regulated independently of the already named process parameters. The temperature control can be carried out with usual measuring methods (using infrared sensors, thermal sensors, etc.).

The method in accordance with the invention can be used to coat components exposed to high process temperatures with a columnar structured abradable coating. Such components are, for example, components of a stationary gas turbine or of an airplane power plant: namely turbine blades, in particular guide blades or runner blades, or even components which can be exposed to hot gas such as a heat shield and shroud.

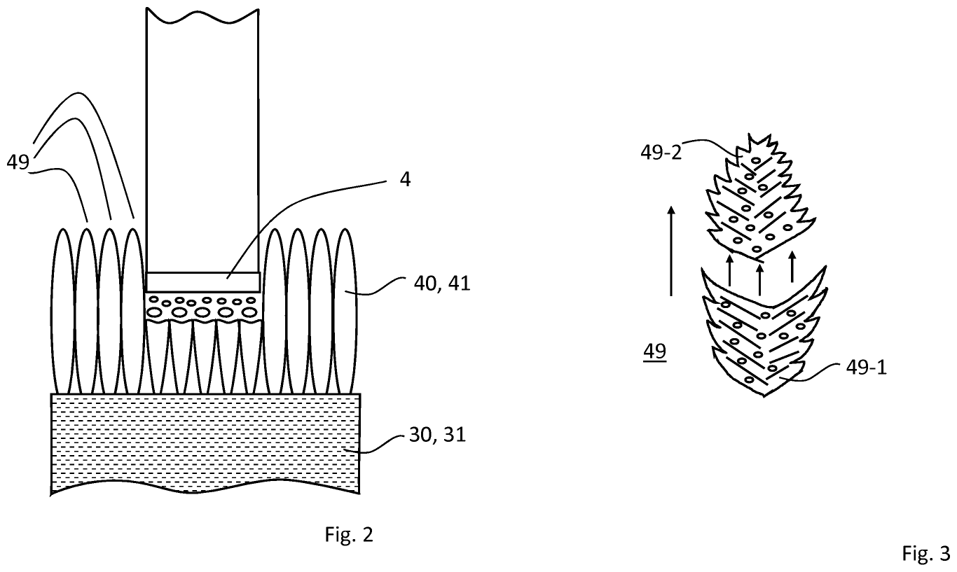

FIG. 2 schematically shows a close-up of the top layers of a coating system, with a TBC 30, respectively an EBC 31 covered with a columnar structured abradable coating 40,41. Also shown is an air foil or vane 3 with a vane-tip 4 of a turbine blade 1 creating a cutting path through the abradable coating 40,41 under operation condition of the turbine. As can be seen, vane 3 creates a well-defined cutting path through the columnar structured abradable coating 40,41. Advantageously, the columnar structured abradable coating has such a low erosion resistance and such a spacing between the individual columns 49 that vane-tip 4 wears of individual columns 49 under the tip without effecting neighbouring columns 49. The columnar structured abradable coating according to the invention has an erosion resistance <30 s/mils, preferably in the range of 5 to 27 s/mils, more preferably in the range 10 to 25 s/mils, even more preferably in the range between 15 and 20 s/mils. Erosion resistances in this range essentially result in that the wall of the cutting path is defined by a single columnar structure 49. The erosion resistance of the columnar structured coating can be tuned by controlling the density of the columnar structures. Lower densities can be realized by reducing and/or removing the amount of Hydrogen plasma gas in the process gas, reducing the surface temperature during the coating process, and increasing the powder feed rate of the coating material. Thus, in an embodiment, the method according to the invention comprises tuning an erosion resistance of the abradable coating through controlling at least one of the amount of hydrogen plasma gas, the surface temperature of substrate 10,11, and the powder feet rate.

The thermal conductivity of the columnar structured abradable coating 40 is similar to a TBC 30, and may be substantially lower in case of very porous coatings, i.e. coatings 40 with a low density of columnar structures 49.

FIG. 3 shows schematically a close-up of the microstructure of a columnar structure 49. As can been seen, the columnar structures 49 have a feathery and loose structure when produced with the PS-PVD process. These feathery structures help reduce the erosion resistance in comparison to a dense crystal growth of needles as is known from EB-PVD. Furthermore, the feathery structure allows vane-tip 4 to create a cutting path by consecutively chipping off individual feathers or feather parts from columnar structure 49 as vane-tip 4 expands under the operating temperature conditions of the turbine. Advantageously, the low or soft erosion resistance of the abradable coating according to the invention allows for a top part 49-2 of the columnar structure to be chipped of by vane-tip 4, while bottom part 49-1 is unaffected and still adheres to the lower layers of the coating system.

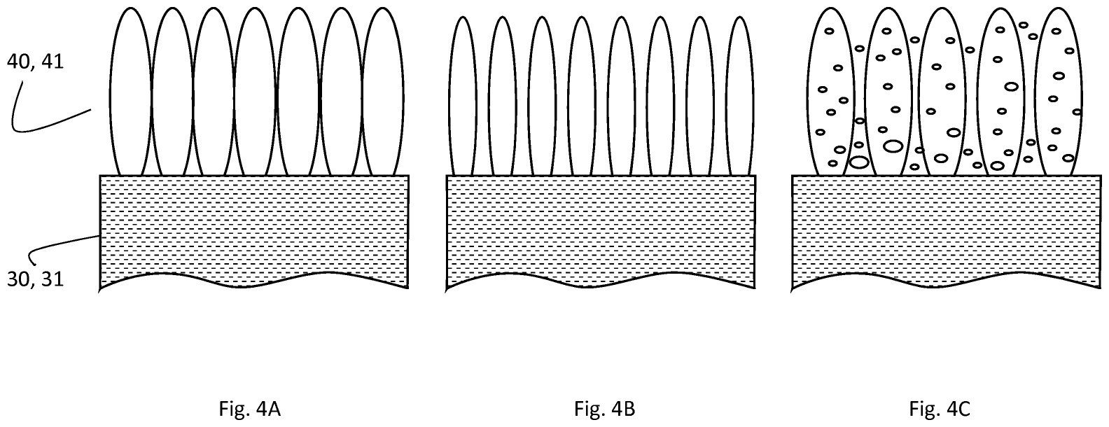

FIG. 4 shows schematically different microstructures of abradable coating 40,41 on top of TBC 30, respectively EBC 31. These can be obtained using the PS-PVD process according to the invention by controlling the coating temperature and the plasma gas mixture. The working pressure and power level of the PS-PVD process are in the same range as described above in conjunction with FIG. 1.

In FIG. 4A a relative dense columnar structure is produced using a plasma mixture of Ar, He, and H₂. Typically, the Ar/He ratio ranges from 2:1 to 1:4, and preferably is 1:2, while the flow rate ranges from 30 to 150 NLPM. The H2 gas flow may range from 1 to 16 NLPM, preferably from 1 to 10 NLPM. As a typical example: the gas flow rate for the PS-PVD process is 30 NLPM Ar, 65 NLPM He, and 10 NLPM H₂. The substrate temperature during the coating process is in the range 700° C. to 1100° C., preferably between 950° C. and 1000° C. The width and linear density of PS-PVD produced columns under these operating conditions is in the range of 10-50 μm with approximately 4 columns/100 μm (i.e. an intercolumn space 0 to 5 μm). Thermal conductivity of such a columnar structured abradable coating is in the range 1.0-2.5 W/m·K.

In FIG. 4B a lower density columnar structure is produced by applying a gas mixture of Ar and He. In other words, the H₂ gas flow has been removed from the mixture. Remaining operation conditions are the same as in FIG. 4A. The width and linear density of PS-PVD produced columns under these operating conditions is in the range of 5-15 μm with approximately 7 columns/100 μm (i.e. an intercolumn space >5 μm). Thermal conductivity of such a columnar structured abradable coating is in the range 0.8-1.5 W/m·K.

In FIG. 4C a crumbly structure is obtained, essentially a mixed phase of the columnar structure and the lamellar dense layer, by reducing the substrate temperature during the deposition process to a temperature in the range 500° C. to 700° C. The remaining operating process conditions are similar as those for FIGS. 4A and 4B. The powder feed rate is a further parameter influencing the mixed phase composition. An increase in the feed rate reduces the number of particles in the vapor phase, thus allowing the tuning of the mixed phase coating.

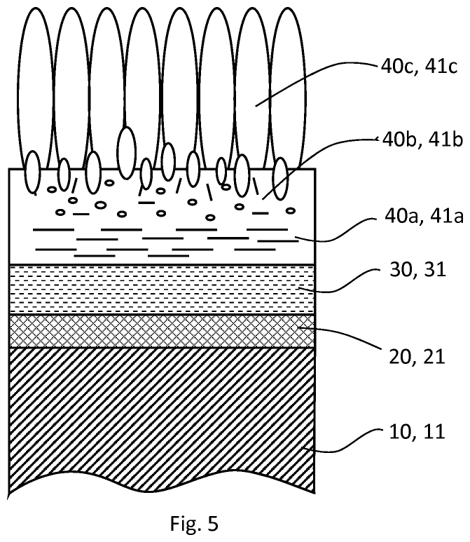

FIG. 5 schematically shows a coating system comprising a gradient abradable coating. The turbine component may have a metallic substrate 10, respectively a CMC substrate 11. Optionally, an appropriate bond coat 20, respectively 21 is applied to the substrate. Subsequently, a TBC layer 30, respectively an EBC layer 31 has been deposited using the PS-PVD process. And on top a gradient abradable coating 40, respectively 41, has been deposited using the PS-PVD process. A first sub-layer 40-a/41-a of gradient coating 40,41 comprises a lamellar dense layer, an optional second sub-layer 40-b/41-b of gradient coating 40, 41 comprises a mixed phase layer, and a third sub-layer at the top comprises a columnar structured abradable layer 40-c/41-c. Advantageously, the gradient ensures an excellent bonding of the abradable coating 40,41 to the underlying TBC 30, respectively EBC 31 layer. Especially in the latter case, in view of the differences in the chemical composition of the EBC and abradable coating layer, the gradient ensures adherence as the chemical composition of the coating material in the three sub-layers may be tuned from one that is commensurate with the EBC to one that is optimal for functioning as a seal to the clearing gap.

Operating parameters for the first sub-layer typically are: work pressure 50 Pa to 80000 Pa, preferably 100 Pa to 1000 Pa; effective power of the plasma jet 40 kW to 80 kW; Total gas flow, comprising Ar and optionally He and/or H₂, in the range of 30 NLPM to 150 NLPM; with, in case the gas flow comprises a Ar/He mixture, an Ar:He ratio in the range 10:1 to 1:1, typically 4:1, and 0<H₂<20 NLPM; a total powder feed rate in the range of 5-120 g/min, preferably 20-80 g/min, ideally between 40 and 80 g/min; substrate temperature in the range of 500° C. to 1100° C.

Operating parameters of the third sub-layer typically are as described for the embodiment in FIG. 1.

Thus, in an embodiment the method comprises depositing a gradient abradable coating by controlling at least one of the substrate temperature, the powder feed rate, and the gas flow mixture. In one example, a first sub-layer 40-a was produced with a 80/40/10 NLPM Ar/He/H2 gas flow mixture, a 2×40 g/min feed rate, a 1.5 mbar work pressure, and a substrate temperature 900° C., while the third sub-layer 40-c was produced with a 30/60/0 NLPM Ar/He/H2 gas flow mixture, a 2×33 10 g/min feed rate, a 1.5 mbar work pressure, an a substrate temperature 1000° C. The working parameters for the second sub-layer 40-b were intermediate to the aforementioned parameter sets.

1-15. (canceled)

16. A method of forming an abradable coating (40,41), comprising
forming a plasma;
introducing a coating material, in the form of a powder having particles in the range between 1 and 50 μm, carried by a delivery gas into the plasma, the plasma having a sufficiently high specific enthalpy for at least partially melting some of the powder and vaporizing at least 5% by weight of the powder, so as to form a vapor phase cloud of vapor and particles;
forming a plasma beam by maintaining a process pressure between 50 and 2000 Pa;
defocussing the plasma beam including the vapor phase cloud; and
forming from the vapor phase cloud onto a substrate (10,11) surface an abradable coating (40, 41), being part of an insulating layer system (20,30,40; 21,31,41), the abradable coating comprising columnar structures (49),
depositing a gradient abradable layer,
wherein depositing a gradient abradable layer comprises depositing a first sub-layer (40-a, 41-a) comprising a lamellar dense structure, a second sub-layer (40-b, 41-b) intermediate between the first sub-layer (40-a, 41-a) and a third sub-layer (40-c, 41-c), wherein the second sub-layer comprises a mixed phase crumbly structure, and the third sub-layer (40-c, 41-c), subsequent to depositing the second sub-layer, comprising the columnar structures (49).

17. The method according to claim 16, wherein the columnar structured abradable coating (40,41) has an erosion resistance smaller than 30 s/mils (equivalent to s/25.4 μm), preferably in the range of 5 to 27 s/mils, more preferably in the range 10-25 s/mils, still more preferably in the range 15-20 s/mils.

18. The method according to claim 17, wherein the method comprises tuning the erosion resistance of the abradable coating (49,41) through controlling at least one of an amount of hydrogen plasma gas, a surface temperature of substrate (10,11), and a powder feet rate.

19. The method according to claim 18, wherein the surface temperature of the substrate (10,11) during the coating process is tuned to a value in the range 500° C. to 1100° C., preferably in the range 950° C. to 1050° C.

20. The method according to 18, wherein the amount of hydrogen plasma gas is tuned in the range of 0 NLPM to 10 NLPM.

21. The method according to claim 18, wherein the total powder feed rate is tuned in the range of 5 g/min to 60 g/min.

22. The method in accordance with claim 16, wherein the columnar structures (49) of abradable coating (40) have a feathery micro-structure.

23. The method in accordance with claim 22, wherein the columnar structures (49) of abradable coating (40) are structured such that, in operation within a turbine or engine, a top part (49-2) of the columnar structure may be chipped away by vane-tip 4, leaving a bottom part (49-1) unaffected.

24. The method according to claim 16, wherein forming the abradable coating comprises using a plasma spray physical vapor deposition (PS-PVD) system.

25. The method according to claim 16, wherein the method comprises forming the first sublayer (41-a) with a chemical composition commensurate with a chemical composition of a lower layer of the insulating layer system and forming the third sub-layer (40-c) with a different chemical composition for forming the columnar structured abradable coating.

26. The method according to claim 16, wherein the substrate (10,11) is a component of a gas turbine.

27. A turbine component or engine component, comprising an insulating layer system (20,30,40; 21,31,41)), wherein the insulating system comprises a gradient abradable layer with a first sub-layer (40-a, 41-a) comprising a lamellar dense structure, a second sub-layer (40-b, 41-b) intermediate between the first sub-layer (40-a, 41-a) and a third sub-layer (40-c, 41-c), with a mixed phase crumbly structure, and the third sub-layer (40-c, 41-c), with a columnar structures (49), such that an outer layer (40,41) of the insulating layer system forms an abradable coating comprising columnar structures (49).
